(19) United States
(12) Patent Application Publication
(10) Pub. No.: US 2012/0166129 A1
(43) Pub. Date: Jun. 28, 2012

(54) CALIBRATION METHOD USING A VECTOR NETWORK ANALYZER AND DELAY TIME MEASUREMENT USING THE SAME

(75) Inventors: Jong-Ho KIM, Daejeon (KR); Myoung-Won Jung, Daejeon (KR); Young-Keun Yoon, Chungbuk (KR)

(73) Assignee: Electronics and Telecommunications Research Institute, Daejeon (KR)

(21) Appl. No.: 13/330,173

(22) Filed: Dec. 19, 2011

(30) Foreign Application Priority Data
Dec. 23, 2010 (KR) 10-2010-0133908

(51) Int. Cl. G06F 19/00; G01R 35/00

(52) U.S. Cl. 702/110

(57) ABSTRACT

Disclosed is a calibration method using a vector network analyzer including: acquiring impulse responses for a direct wave and a multi-reflected wave generated by transmitting and receiving devices connected to a measuring port of the vector network analyzer; setting a gate only for an impulse response for the direct wave among the impulse responses for the acquired direct wave and multi-reflected wave; and transforming the impulse response for the direct wave to which the gate is set into a frequency domain signal and defining the transformed frequency domain signal as calibration results.

### CROSS-REFERENCE TO RELATED APPLICATIONS

The present application claims priority of Korean Patent Application No. 10-2010-0133908, field on Dec. 23, 2010, which is incorporated herein by reference in its entirety.

### BACKGROUND OF THE INVENTION

1. Field of the Invention

Exemplary embodiments relate to a calibration method using a vector network analyzer and a method for measuring delay time using the same, and more particularly, to a method for performing accurate calibration by removing all reflected waves causing interference using a function of a vector network analyzer (VNA) when measuring propagation delay time of the reflected waves transmitted between transmitter and receiver antennas using the vector network analyzer (VNA) and a method for measuring the delay time based on the performed calibration.

2. Description of Related Art

In a digital communication system such as a wired, wireless, and optical system, transmitted signals wirelessly reach a receiver through a wireless channel. In the wireless channel, the transmitted signals interact with a surrounding environment in a very complicated manner. For example, when the signals are transmitted through a wireless communication channel, the received wireless signals may have various types of damages due to reflection from large obstacles, diffraction around edges of smaller obstacles, and refraction due to media and signal dispersion.

Therefore, the related art measures delay time of reflected waves due to multiple reflection in a time domain by using a vector network analyzer (VNA) to perform calibration, thereby preventing signals from interfering with each other.

A process of measuring the delay time of the reflected waves due to the multiple reflection in the time domain by using the vector network analyzer (VNA) will be described below.

First, a frequency domain is determined. Therefore, the calibration is performed for each measuring port in the determined frequency domain. Further, the measurement is performed in the determined frequency domain by connecting a transceiver to each measuring port. Then, the results measured in the frequency domain are finally subjected to inverse fast Fourier transform (IFFT) and are transformed into a value of the time domain, thereby measuring the delayed time of each reflected wave.

In this case, when an amplifier, an antenna, or the like, are connected with the measuring port, the calibration data may be distorted in the frequency domain by devices such as the amplifier or the antenna.

In order to prevent the problems, after essential devices such as an amplifier, a filter, or the like, are connected to each measuring port, through calibration is performed by mounting transmitter and receiver antennas to be adjacent to the devices as maximally as possible. The through calibration, which is one of the calibration methods, is based on signal strength between two ports of the VAN.

However, even though the through calibration is performed, errors may occur in the antenna due to the multiple reflection. That is, for the accurate calibration, only one propagation path is present in the transmitter and receiver antenna. However, the reflected waves are generated by several objects around the antenna and these generated reflected waves affect the received signals, thereby distorting the desired signals.

In the related art, in order to solve the above-mentioned problems, the calibration was performed by using an anechoic chamber under the environment in which the reflected waves are not generated. However, whenever the calibration is performed, the calibration needs to be performed in the anechoic chamber. Therefore, much cost incurs due to the expensive anechoic chamber.

### SUMMARY OF THE INVENTION

An embodiment of the present invention is directed to a method for performing accurate calibration by removing all the reflected waves causing interference by using a function of a vector network analyzer (VAN) when measuring propagation delay time of reflected waves transmitted between transmitter and receiver antennas by using the vector network analyzer (VNA).

Another embodiment of the present invention is directed to a method for measuring propagation delay time of transmitting and receiving devices to be measured based on accurate calibration results.

The objects of the present invention are not limited to the above-mentioned objects and therefore, other objects and advantages of the present invention that are not mentioned may be understood by the following description and will be more obviously understood by exemplary embodiments of the present invention. In addition, it can be easily appreciated that objects and advantages of the present invention may be implemented by means and a combination thereof described in claims.

In accordance with an embodiment of the present invention, a calibration method using a vector network analyzer includes: acquiring impulse responses for a direct wave and a multi-reflected wave generated by transmitting and receiving devices connected to a measuring port of the vector network analyzer; setting a gate only for an impulse response for the direct wave among the impulse responses for the acquired direct wave and multi-reflected wave; and transforming the impulse response for the direct wave to which the gate is set into a frequency domain signal and defining the transformed frequency domain signal as calibration results.

In one embodiment, the setting of the gate may be set a starting time and an ending time of the impulse response for the direct wave among the impulse responses for the direct wave and the multi-reflected wave to be a starting time and an ending time of filtering.

In accordance with another embodiment of the present invention, a method for measuring delay time using a vector network analyzer includes: acquiring an impulse response for a direct wave and a multi-reflected wave generated by transmitting and receiving devices connected to a measuring port of the vector network analyzer; setting a gate only for the impulse response for the direct wave among the impulse responses for the acquired direct wave and multi-reflected wave; and transforming an impulse response for the direct wave to which the gate is set into a frequency domain signal and defining the transformed frequency domain signal as calibration results; and transforming measurement results in another frequency domain into a time domain based on the calibration results to measure delay time.

In one embodiment, the transforming of the measurement results in another frequency may transform frequency domain results measured based on the calibration results into a time domain by inverse fast Fourier transform to measure delay time.

### BRIEF DESCRIPTION OF THE DRAWINGS

FIG. 1 is a diagram illustrating calibration connection and characteristics of time domain response and frequency domain response for measuring delay time by using a vector network analyzer (VAN).

FIG. 2 is a diagram for describing a system for measuring delay time using the vector network analyzer (VNA) and the characteristics of the time domain response and the frequency domain response at the time of measurement.

FIG. 3 is a diagram for describing the system for measuring delay time using the vector network analyzer (VNA) for describing an operating principle of the embodiment of the present invention and the characteristics of the time domain response and the frequency domain response at the time of measurement.

FIG. 4 is a flow chart for describing a method for measuring delay time using the vector network analyzer in accordance with the embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

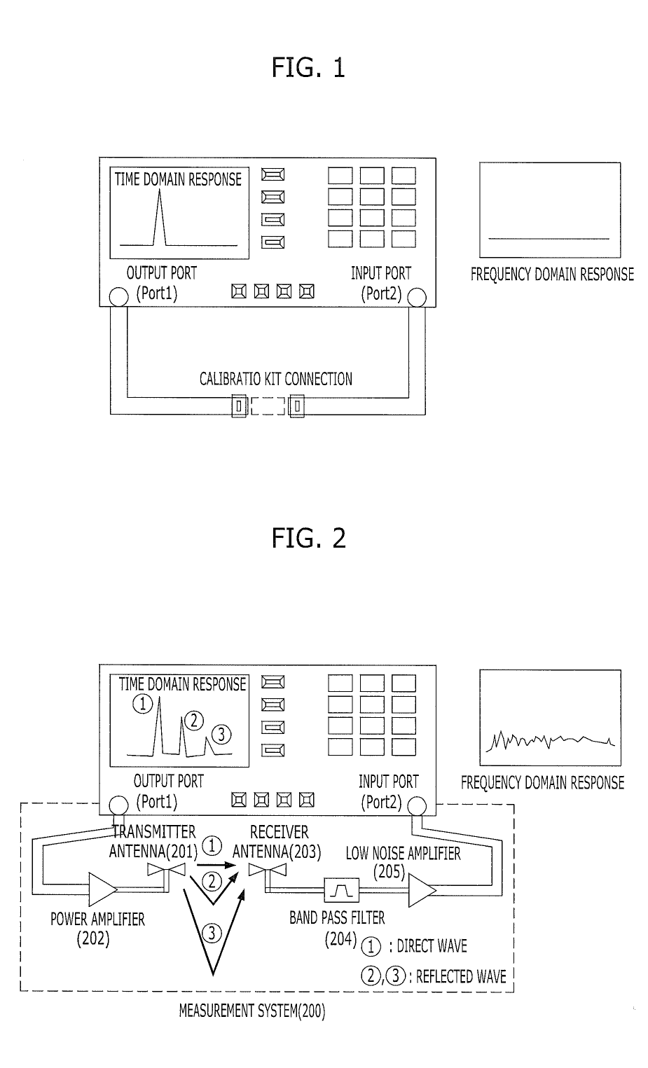

FIG. 1 is a diagram illustrating calibration connection and characteristics of time domain response and frequency domain response for measuring delay time by using a vector network analyzer (VAN).

The calibration is performed by using the existing method using the vector network analyzer (VNA) in a state in which transmitting and receiving devices are not connected with a measuring port.

Referring to FIG. 1, a vector network analyzer (VNA) 100 is connected with a calibration kit through a cable.

First, a calibrator sets a specific frequency band through the vector network analyzer (VAN) 100 and performs the calibration through the calibration kit connected to two measuring ports in the predetermined specific frequency domain. Further, the characteristics of the output time domain response signal and frequency domain response signal are confirmed according to the calibration results.

FIG. 2 is a diagram for describing a system for measuring delay time using the vector network analyzer (VNA) and the characteristics of the time domain response and the frequency domain response at the time of measurement.

As illustrated in FIG. 1, the calibration is performed by using the calibration kit. Thereafter, as illustrated in FIG. 2, the calibrator connects transmitting and receiving devices for measurement to measuring ports (port 1 and port 2), respectively, of the vector network analyzer (VAN) 100 and measures the delay time of the transmitted propagation.

The transmitting device for measurement is configured to include a power amplifier 202 and a transmitter antenna 201 and the receiving device for measurement is configured to include a receiver antenna 203, a band pass filter 204, and a low noise amplifier 205.

In order to measure the delay time of the transmitting and receiving devices by using the vector network analyzer (VNA), the transmitting device is connected to the first port (port 1) through a cable and the receiving device is connected to the second port (port 2) through a cable. Further, signals are transmitted from the transmitting device to the receiving device by operating the transmitting device and the receiving device. In this case, the transmitter antenna approaches the receiver antenna, thereby performing the measurement in the time domain.

In this case, the signals radiated through the transmitter antenna are multi-reflected according to the given environment and are transmitted to the receiver antenna. Therefore, a direct wave and a multi-reflected wave are present between the transmitter antenna and the receiver antenna.

Referring to FIG. 2, the time domain response for the direct wave and the multi-reflected wave may be measured through the vector network analyzer (VAN). In addition, referring to FIG. 2, the frequency domain response may be confirmed under the aforementioned measurement environment.

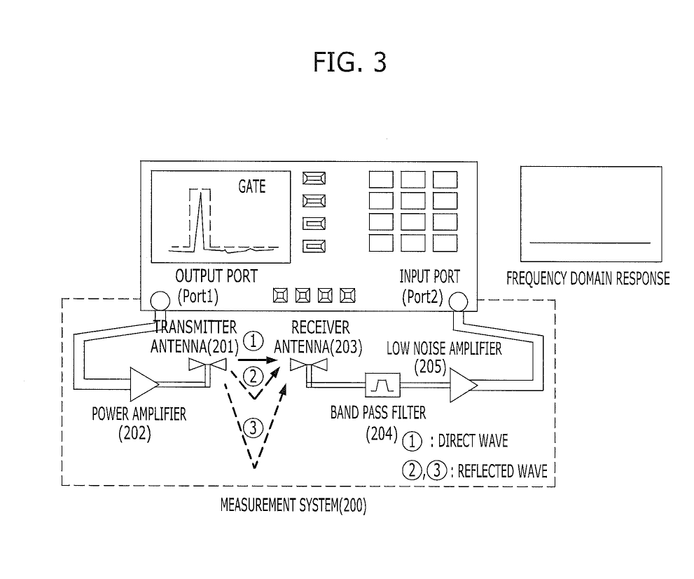

FIG. 3 is a diagram for describing the system for measuring delay time using the vector network analyzer (VNA) for describing an operating principle of the embodiment of the present invention and the characteristics of the time domain response and the frequency domain response at the time of measurement.

As described in FIG. 2, the time domain response for the direct wave and the multi-reflected wave may be confirmed through the vector network analyzer (VNA) 100.

In this case, the embodiment of the present invention, in order to improve the accuracy of the measurement results, a gate is set by searching an impulse response for the direct wave in the plurality of time domain responses. The gate is a function provided by the vector network analyzer (VNA) and serves to provide the filtering function in the time domain.

Referring to FIG. 2, since the time response time of the direct wave is generally fastest, the earliest generated impulse in time among the plurality of displayed impulse response signals is determined as the impulse response signal for the direct wave.

Therefore, only the direct wave may be received by setting the gate for only the searched direct wave as illustrated in FIG. 3. Therefore, the gate may receive only the direct wave and may not receive the multi-reflected wave, among the radio waves generated between the transmitter antenna and the receiver antenna.

In other words, the gate sets the starting time and the ending time of the earliest generated impulse response signal, that is, the impulse response signal for the direct wave to be the starting time and the ending time of the filtering and thus, passes through only the impulse response corresponding to the set starting time and ending time, thereby filtering only the impulse response signal for the direct wave. Therefore, the gate passes through only the impulse response signal for the direct wave and the does not receive impulse response signals due to the remaining multi-reflected waves.

Next, the gate again transforms the impulse response for the filtered direct wave into the signal in the frequency domain. Therefore, the results in the transformed frequency domain correspond to the results in the frequency domain for the direct wave from which the reflected waves are removed. The measurement results in the frequency domain for the direct wave correspond to the calibration results of the embodiment of the present invention and the measurement results in the time domain can be obtained when the measurement is performed in another time domain.

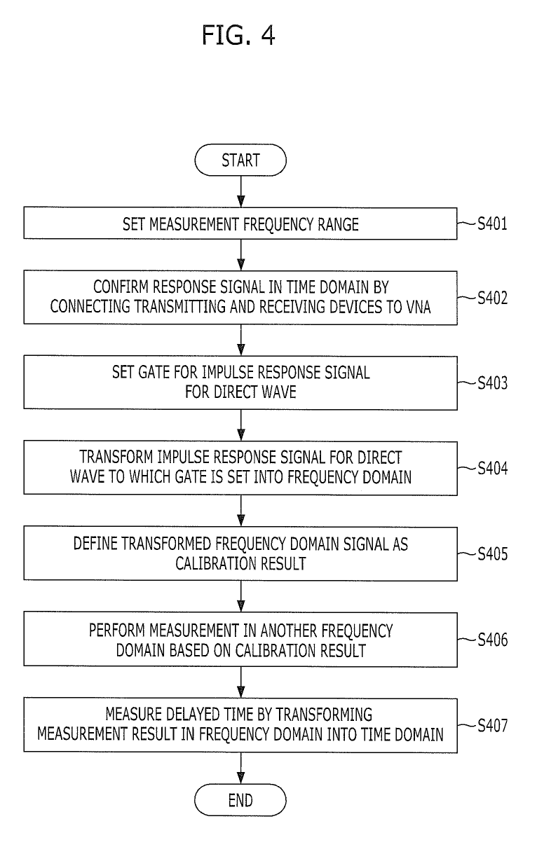

FIG. 4 is a flow chart of an embodiment of a method using a vector network analyzer in accordance with the present invention.

Generally, in the system for measuring delay time, the transmitting and receiving devices to be measured are connected to the vector network analyzer (VNA), wherein the vector network analyzer (VNA) is connected to a computer for analyzing control and measurement results.

First, a measurement frequency range for delay time measurement is set (S401). Further, the vector network analyzer (VNA) is connected to the transmitting and receiving devices and the time domain response signal for the direct wave and the multi-reflected wave is confirmed by generating the signal (S402).

Further, for the accurate calibration, the gate is set only for the time domain response signal for the direct wave among the time domain response signal for the direct wave and the multi-reflected wave.

In addition, the impulse response signal in the state in which the gate is set is transferred to the computer. In this case, the impulse response signal for the pure direct wave is transformed into the frequency domain signal in the computer (S404) and the frequency domain signal for the transformed direct wave is defined as the calibration results (S405). Through the above-mentioned process, the accurate calibration results can be acquired even though the anechoic chamber is not used.

Thereafter, the measurement in another frequency domain of the device to be measured is performed based on the calibration results (S406) and the measured frequency domain results are transformed into the time domain through the inverse fast Fourier transform (IFFT) to measure the delayed time for each frequency (S407).

Meanwhile, the method in accordance with the embodiment of the present invention can be prepared by a computer program. Further, a code and a code segment configuring the program may be easily inferred by a computer programmer in the art. In addition, the prepared programs are stored in a computer readable recording medium (information storage medium) and are read and executed by the computer, thereby implementing the method of the present invention. Further, the recording medium includes all the types of computer readable recording media.

As set forth above, the exemplary embodiments of the present invention can accurately perform the calibration by removing all the reflected waves other than the direct waves by applying the gate function of the vector network analyzer to the direct waves when performing the calibration by using the vector network analyzer, thereby accurately measuring the delay time between the transmitter and receiver antennas.

While the present invention has been described with respect to the specific embodiments, it will be apparent to those skilled in the art that various changes and modifications may be made without departing from the spirit and scope of the invention as defined in the following claims.

What is claimed is:

1. A calibration method using a vector network analyzer, comprising:
acquiring impulse responses for a direct wave and a multi-reflected wave generated by transmitting and receiving devices connected to a measuring port of the vector network analyzer;
setting a gate only for an impulse response for the direct wave among the impulse responses for the acquired direct wave and multi-reflected wave; and
transforming the impulse response for the direct wave to which the gate is set into a frequency domain signal and defining the transformed frequency domain signal as calibration results.

2. The method of claim 1, wherein the setting of the gate sets a starting time and an ending time of the impulse response for the direct wave among the impulse responses for the direct wave and the multi-reflected wave to be a starting time and an ending time of filtering.

3. A method for measuring delay time using a vector network analyzer, comprising:
acquiring an impulse response for a direct wave and a multi-reflected wave generated by transmitting and receiving devices connected to a measuring port of the vector network analyzer;
setting a gate only for the impulse response for the direct wave among the impulse responses for the acquired direct wave and multi-reflected wave; and
transforming an impulse response for the direct wave to which the gate is set into a frequency domain signal and defining the transformed frequency domain signal as calibration results; and
transforming measurement results in another frequency domain into a time domain based on the calibration results to measure delay time.

4. The method of claim 3, wherein the setting of the gate sets a starting time and an ending time of the impulse response for the direct wave among the impulse responses for the direct wave and the multi-reflected wave to be a starting time and an ending time of filtering.

5. The method of claim 3, wherein the transforming of the measurement results in another frequency transforms frequency domain results measured based on the calibration results into a time domain by inverse fast Fourier transform to measure delay time.
